(19) United States
(12) Patent Application Publication
(10) Pub. No.: US 2026/0324484 A1
(43) Pub. Date: Oct. 15, 2026

(54) INTERFACES FOR COUPLING SEMICONDUCTOR SYSTEMS WITH SOLDER-MASKED SUBSTRATES

(71) Applicant: Micron Technology, Inc., Boise, ID (US)

(72) Inventors: Kelvin Aik Boo Tan, Singapore (SG); See Hiong Leow, Singapore (SG); Hong Wan Ng, Singapore (SG); Chin Hui Chong, Singapore (SG); Seng Kim Ye, Singapore (SG)

(21) Appl. No.: 19/638,976

(22) Filed: Apr. 3, 2026

Related U.S. Application Data
(60) Provisional application No. 63/786,856, filed on Apr. 10, 2025.

(51) Int. Cl. H10W 72/20; B23K 1/00; B23K 1/20; C23C 18/16; C23C 18/38; C25D 5/54; H10W 70/05; H10W 70/695; H10W 90/00; B23K 101/40

(52) U.S. Cl. CPC H10W 72/227; B23K 1/0016; B23K 1/20; C23C 18/1653; C23C 18/38; C25D 5/54; H10W 70/05; H10W 70/695; H10W 90/724; B23K 2101/40

(57) ABSTRACT

Methods, systems, and devices for interfaces for coupling semiconductor systems with solder-masked substrates are described. An electronic system may include an electronic substrate, such as a printed circuit board assembly, that includes first circuitry and a solder mask material along a surface of the electronic substrate. The electronic system may include a semiconductor system that includes second circuitry of one or more semiconductor dies. One or more first conductor portions may be soldered to the electronic substrate at a level below the solder mask material and may couple the second circuitry with the first circuitry. One or more second conductor portions may be soldered to one or more third conductor portions of the electronic substrate at a level above the solder mask material. The one or more third conductor portions may extend through the solder mask material or may be above the solder mask material.

### CROSS REFERENCE

The present Application for Patent claims priority to U.S. Patent Application No. 63/786,856 by Tan et al., entitled “INTERFACES FOR COUPLING SEMICONDUCTOR SYSTEMS WITH SOLDER-MASKED SUBSTRATES,” filed Apr. 10, 2025, which is assigned to the assignee hereof, and which is expressly incorporated by reference in its entirety herein.

### TECHNICAL FIELD

The following relates to one or more semiconductor systems, including interfaces for coupling semiconductor systems with solder-masked substrates.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports interfaces for coupling semiconductor systems with solder-masked substrates in accordance with examples as disclosed herein.

FIG. 2 shows examples of systems that support interfaces for coupling semiconductor systems with solder-masked substrates.

FIG. 3A through 3F illustrate examples of fabrication operations that support interfaces for coupling semiconductor systems with solder-masked substrates in accordance with examples as disclosed herein.

FIG. 4A through 4E illustrate examples of fabrication operations that support interfaces for coupling semiconductor systems with solder-masked substrates in accordance with examples as disclosed herein.

FIGS. 5 and 6 show flowcharts illustrating a method or methods that support interfaces for coupling semiconductor systems with solder-masked substrates in accordance with examples as disclosed herein.

### DETAILED DESCRIPTION

Some electronic systems (e.g., memory systems, processor systems, flip-chip die packages, a high bandwidth memory (HBM) system, a coupled dynamic random access memory (DRAM) system) may include semiconductor systems (e.g., a die, a chip, a DRAM device) that are bonded (e.g., stacked, coupled, mounted) over a package substrate (e.g., a die substrate, a printed circuit board (PCB)). A semiconductor system may include structures, such as on-die pillars (ODPs), that provide mechanical support for the device package (e.g., the bonded set of components), electrical connections between the semiconductor system and the substrate, or both. For example, such structures may distribute various stresses (e.g., compressions, impacts, bending) experienced by the bonded package, thereby enhancing the overall reliability of the system. Some ODP designs may include a solder bond with a conductor pad on a surface of the package substrate (e.g., below a solder mask material formed along a surface of the substrate). However, a substrate surface may include circuitry such as signal routing traces and power distribution networks, among other examples. The substrate circuitry may impose constraints on the placement of ODP structures, because at least some ODPs may not be coincident with areas of the substrate surface occupied by circuitry (e.g., ODPs may be constrained to areas that are free of substrate surface circuitry). Such designs may limit the ability of ODPs (e.g., or other similar structures) to relieve stress for the package (e.g., may limit a quantity of ODPs that are used) and may also increase design complexity.

In accordance with one or more techniques described herein, an electronic system may include ODP structures (e.g., conductor portions) that support a bond (e.g., solder attachments, mechanical connections) at a top surface of a substrate solder mask material. Such designs may, for example, mitigate package stress without interfering with the underlying circuitry of the substrate. In some examples, a semiconductor system may include a first type of ODP (e.g., Type 1) that is bonded (e.g., coupled, soldered, mounted) to a conductive pad (e.g., an interconnection landing pad, a metallic pad) located at the solder mask surface and extending through the solder mask to couple with a conductive portion below the solder mask surface (e.g., a ground plane). In some examples, the first type of ODP may be associated with improved electrical performance and package reliability (e.g., based on an improved grounding scheme supports by the ODPs). Additionally, or alternatively, the semiconductor system may include a second type of ODP (e.g., Type 2) that is bonded with landing pads formed over (e.g., not through) the solder mask surface (e.g., a metallic pad sputter). The second type of ODP may be associated with reduced implementation complexity, for example, by supporting ODP placement that is independent of substrate circuitry layout. By applying one or more techniques herein an electronic system may be enabled to support an increased quantity of ODPs and improved ODP isolation from substrate circuitry, which provide increased mechanical stability and enhanced electrical performance, among other benefits.

In addition to applicability in memory systems as described herein, interfaces for coupling semiconductor systems with solder-masked substrates may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by improving device integrity and reliability, which may extend the life of electronic devices and thereby reducing electronic waste, among other benefits.

Features of the disclosure are illustrated and described in the context of systems and architectures. Features of the disclosure are further illustrated and described in the context of operations and flowcharts.

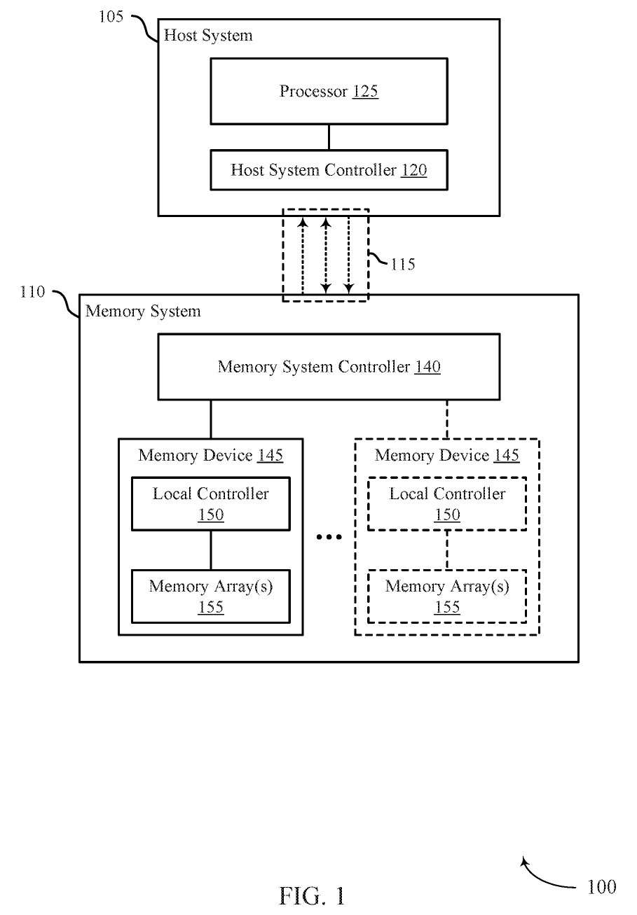

FIG. 1 shows an example of a system 100 that supports interfaces for coupling semiconductor systems with solder-masked substrates in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

Signaling may be communicated over the channels 115 using single data rate (SDR) signaling or double data rate (DDR) signaling, among other rates (e.g., relative to a clock signal). In SDR signaling, one modulation symbol (e.g., signal level) of a signal may be registered for each clock cycle (e.g., on a rising edge or a falling edge of a clock signal). In DDR signaling, two modulation symbols of a signal may be registered for each clock cycle (e.g., on both a rising edge and a falling edge of a clock signal).

Signals communicated over the channels 115 may be modulated using various modulation schemes or combinations thereof. A symbol of a binary-symbol (e.g., binary-level) modulation scheme may be operable to represent one bit of data (e.g., a symbol may represent a logic 1 or a logic 0), and may be an example of an M-ary modulation scheme where M is equal to two. Examples of binary-symbol modulation schemes include non-return-to-zero (NRZ), unipolar encoding, bipolar encoding, Manchester encoding, pulse amplitude modulation (PAM) having two symbols (e.g., PAM2), and others. A symbol of a multi-symbol modulation scheme may be operable to represent more than one bit of data (e.g., a symbol may represent a logic 00, a logic 01, a logic 10, or a logic 11), and may be an example of an M-ary modulation scheme where M is greater than or equal to three. For example, a multi-symbol signal may be modulated using a modulation scheme that includes at least three levels to encode more than one bit of information. Multi-symbol modulation schemes and symbols may be referred to as non-binary, multi-bit, or higher-order modulation schemes and symbols. Examples of multi-symbol modulation schemes include PAM3, PAM4, PAM8, and so on, quadrature amplitude modulation (QAM), quadrature phase shift keying (QPSK), and others.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks, or in one or more other dies. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with one or more logic dies (e.g., that include aspects of the host system 105, that is coupled with another set of one or more dies that includes the host system 105) that includes interface blocks operable to access a set of memory arrays 155 distributed across the one or more second dies.

In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host system 105, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

Some systems 100 may include one or more semiconductor systems (e.g., a set of one or more dies, a set of one or more chips, of a memory system 110 or portion thereof, or a host system 105 or portion thereof) that are soldered to a package substrate (e.g., a die substrate, a PCB substrate). A semiconductor system may include structures, such as ODPs, that provide mechanical support for the system 100, electrical connections across devices in the system 100 (e.g., channels 115), or both. Some ODP designs may include a solder bond with a landing pad located on a surface below a solder mask material formed over the substrate. However, a substrate surface may include circuitry, such as signal routing traces and power distribution networks, that may impose constraints on the placement of ODP structures (e.g., ODPs may be constrained to areas that are free of substrate surface circuitry). Such designs may thereby limit the ability of the ODP (e.g., or other similar structures) to relieve stress for components of the system 100.

In accordance with aspects described herein, one or more components of a system 100 may include ODP structures (e.g., conductor portions) that support a bond (e.g., solder-based bond, a mechanical connection) at a top surface of the substrate solder mask material. In some examples, the system 100 may include a first type of ODP (e.g., Type 1) that is bonded with a conductive pad located at the solder mask surface and extending through the solder mask to couple with a conductive portion below the solder mask surface (e.g., a ground plane). Additionally, or alternatively, the system 100 may include a second type of ODP (e.g., Type 2) that is bonded with landing pads formed over (e.g., not through) the solder mask surface (e.g., a metallic pad sputter). By applying one or more techniques herein the system 100 may be enabled to support an increased quantity of ODPs and improved ODP isolation from substrate circuitry, which provide increased mechanical stability and enhanced electrical performance, among other benefits.

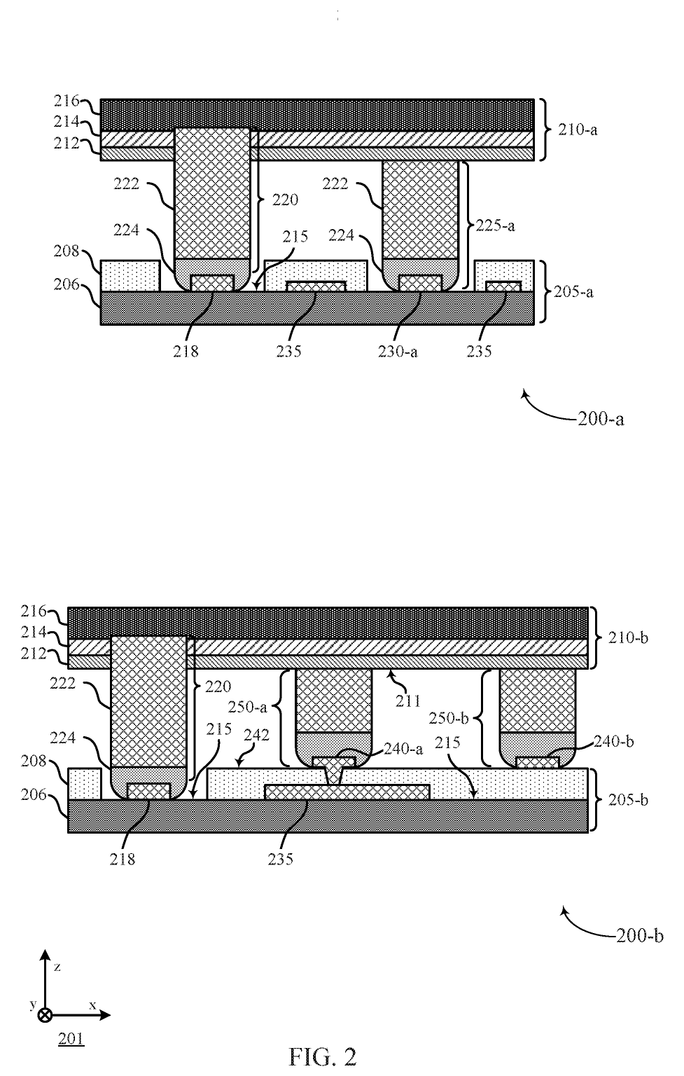

FIG. 2 shows examples of systems 200 (e.g., electronic systems) that support interfaces for coupling semiconductor systems with solder-masked substrates. A system 200 may be an example of or include one or more aspects of a system 100, and may be described with reference to an x-direction, a y-direction, and a z-direction of a coordinate system 201.

A system 200 may include a substrate 205 (e.g., an electronic substrate, a die substrate, a PCB, a substrate including alternating layers of conductive traces and a dielectric composite, such as a fiberglass-reinforced epoxy laminate, FR4, or bismaleimide triazine (BT)) and a semiconductor system 210 (e.g., a semiconductor component, a semiconductor die, a set of multiple semiconductor dies, a stack of semiconductor dies, a memory array die, a flip-chip die), such as the substrate 205-a, the substrate 205-b, the semiconductor system 210-a, or the semiconductor system 210-b. A semiconductor system 210 may be an example of or include a memory system 110 (e.g., one or more memory devices 145, a memory system controller 140) or a host system 105 (e.g., a processor 125, a host system controller 120), or a portion thereof, among other examples. Although each substrate 205 is illustrated in FIG. 2 as being bonded with a single semiconductor system 210, a substrate 205 may be bonded with any quantity of one or more semiconductor systems 210 in accordance with the described techniques (e.g., on one side of a substrate 205, on multiple sides of a substrate 205). Although a system 200 may implement one or more semiconductor systems 210, the described techniques may be implemented in accordance with other types of electronic devices.

A substrate 205 may include a circuitry portion 206 (e.g., including circuitry, such as substrate circuitry) and a solder mask material 208 (e.g., a solder mask, a solder stop mask, a solder resist) that is formed along (e.g., on, at, covering at least a portion of) a surface 215 of the circuitry portion 206. The circuitry portion 206 may include functional circuitry (e.g., processing circuitry, filtering circuitry, power supply circuitry), interconnection circuitry (e.g., conductive lines or multiplexing circuitry for interconnecting components, such as semiconductor systems 210, coupled with the substrate), interface circuitry (e.g., conductive lines and contacts for coupling with a component external to the system 200), or any combination thereof. The solder mask material 208 may be formed along the x-direction and the y-direction of system 200, spanning at least a portion of the surface 215. The surface 215 may be referred to as a surface of the substrate 205. The solder mask material 208 may be a layer of polymer (e.g., a lacquer, which may be different than a dielectric material of a circuitry portion 216), which may protect a circuitry portion 206 from degradation (e.g., oxidation, environmental degradation), or may prevent solder bridges from forming between electrical contacts, among other functions.

A semiconductor system 210 may include one or more material layers or portions. For example, a semiconductor system 210 may include a circuitry portion 216 (e.g., including circuitry of one or more semiconductor dies, such as one or more memory dies, one or more processor dies, dies of an HBM system, dies of a 3D stacked memory system) and one or more dielectric layers, such as a polyimide material 212 (e.g., one or more polyimide material layers), a dielectric material 214 (e.g., one or more dielectric material layers), or a combination thereof. A polyimide material 212 (e.g., a direct chip attach (DCA) die polyimide) may refer to a polymer associated with relatively high thermal stability, high mechanical strength, and electrical insulation properties. A dielectric material 214 may, in some cases, include a material associated with a relatively low dielectric constant (e.g., referred to as “low-k” dielectric material, a dielectric constant lower than a threshold, a silicon oxide, a silicon nitride, or other dielectric material), which may reduce parasitic capacitance between components of the system 200. A circuitry portion 216 may include semiconductor circuitry such as transistor circuitry, memory array circuitry, logic circuitry, processing circuitry, other functional system circuitry, or a combination thereof.

A system 200 (e.g., system 200-a) may include one or more structures, such as one or more active pillars 220 (e.g., conductor portions, communicative pillars, which may also be ODPs), one or more ODPs 225 (e.g., conductor portions, dummy pillars, interconnect structures), or both that support a bond (e.g., a connection, a coupling) between a substrate 205 and one or more semiconductor systems 210. Active pillars 220 and ODPs 225 may include one or more conductive materials including, for example, a conductive material 222 (e.g., copper) and a conductive material 224 (e.g., solder). Active pillars 220 or ODPs 225 may, in some examples, also include one or more conductive material layers (not shown) along the z-direction, including a layer between the conductive material 222 and the conductive material 224. Active pillars 220, ODPs 225 (or a portion thereof, such as conductive material 222), or both may be considered to be components of a semiconductor system 210, and may be formed with the semiconductor system 210 before bonding with a substrate 205.

An active pillar 220 may support a communicative coupling between a semiconductor system 210-a (e.g., a circuitry portion 216) and a substrate 205-a (e.g., a circuitry portion 206), such as being formed through polyimide material 212 and dielectric material 214. As such, an active pillar 220 may support connections between circuitry of a circuitry portion 216 and circuitry of a circuitry portion 206. For example, at a first end (e.g., an end along the negative z-direction, a bottom end) an active pillar 220 may be coupled with (e.g., bonded with, soldered with) circuitry of a substrate 205 (e.g., of a circuitry portion 206) such as via a conductor 218, which may be a conductive contact, coupled with circuitry of a circuitry portion 206, that is exposed during a bonding operation. Additionally, or alternatively, at a second end opposite the first end (e.g., an and along the positive z-direction, a top end), the active pillar 220 may be coupled with circuitry of a semiconductor system 210 (e.g., of a circuitry portion 216).

In some examples, an ODP 225 may be formed at (e.g., standing on) a dielectric layer, such as a polyimide material 212, of a semiconductor system 210. As such, an ODP 225 may support a mechanical coupling between a semiconductor system 210 and a substrate 205 without (e.g., may not support) a communicative coupling. For example, at a first end (e.g., an end along the positive z-direction, a top end) an ODP 225 may be in contact with polyimide material 212 of a semiconductor system 210 (e.g., and may not couple with circuitry of the semiconductor system 210, such as a circuitry portion 216). At a second end opposite the first end (e.g., an end along the negative z-direction, a bottom end) the ODP 225 may be coupled with a conductor 230 (e.g., a conductor portion, a landing pad, a pad that supports solder bonding, an interconnection contact point).

In some cases, dielectric material 214 (e.g., one or more low-k dielectric materials) may be associated with reduced structural integrity and may reduce chip-package interaction (CPI) performance. As such, a system 200 may be designed to include one or more ODPs 225 to improve mechanical performance of the system 200 under various load conditions (e.g., may transfer stress from dielectric material 214 to the ODP(s) 225). However, some designs for ODPs 225 may provide a limited benefit for a system 200 (e.g., system 200-a). For instance, an ODP 225-a may be bonded with a conductor 230-a (e.g., a substrate layer landing pad) that is formed at the surface 215 of the substrate 205-a (e.g., and underneath a surface of the solder mask material 208, the landing pad may be on the substrate 205-a).

In some cases, having conductors 230-a along a surface 215 for bonding with ODPs 225 may present various challenges. For instance, to accommodate the conductor 230-a used for bonding with the ODP 225-a, an active metal layer (e.g., along the surface 215) of the substrate 205-a and the solder mask material 208 may undergo complex redesign. For example, active metal layer adjustment may affect signal routing, a power plane configuration, a ground plane configuration, and signal quality, among other changes. In some examples, an assessment of electrical performance may be performed for each adjustment of ODPs 225 (e.g., to verify electrical performance). Moreover, a position of ODPs 225 may be constrained based on circuitry of a substrate 205 (e.g., a substrate 205-a, of a circuitry portion 206, a substrate routing area). For example, placement of ODPs 225 may be limited to areas that do not include circuitry at the surface 215, which may thus limit a quantity of ODPs 225 supported by a system 200, such as system 200-a. As such, an ability of ODPs 225 to reduce mechanical stress experienced by other components may be limited. Moreover, utilizing ODPs 225 may be associated with decreased electrical performance, reduced system reliability, and increased design complexity, among other effects.

As described herein, a system 200 (e.g., system 200-b) may include one or more ODPs 250 (e.g., ODP(s) 250-a, ODP(s) 250-b, or a combination thereof, along with one or more active pillars 220) that mitigate package stress (e.g., CPI stress) without altering the design of the substrate 205 (e.g., without altering a circuitry portion 206, without altering the package substrate metal layer design). For example, the system 200-b may include one or more ODPs 250-a, one or more ODPs 250-b, or a combination thereof that support bonding with conductors 240 (e.g., a conductor portion, a metallic pad) that are formed at (e.g., in contact with) the solder mask material 208 of the substrate 205-b (e.g., the conductor 240 may provide an interconnection landing pad for the ODP 250). Because ODPs 250-a and 250-b terminate at a surface 242 (e.g., solder mask surface), ODPs 250 may be flexibly allocated at various locations of the system 200-b (e.g., along the x-direction, along the y-direction, or both). Accordingly, ODPs 250 may be incorporated into the system 200-b independent (e.g., irrespective) of the substrate circuitry routing, as well as with reduced (e.g., or without) metal layer redesign adjustments and reassessments of electrical performance.

An ODP 250-a may be a first type of ODP 250 (e.g., Type 1). For example, an ODP 250-a may include a solder bond with a conductor 240-a. The conductor 240-a may be a metallic pad on the surface 242 and may (e.g., by way of a via through the solder mask material 208) be coupled with a conductor 235 (e.g., a conductor portion) of the substrate 205-b. The conductor 235 may be associated with a ground plane of the substrate 205-b (e.g., of a circuitry portion 206), such that an ODP 250-a may be grounded at the substrate 205-b. An ODP 250-b may be a second type of ODP 250 (e.g., Type 2). For example, an ODP 250-b may include a solder bond with a conductor 240-b. The conductor 240-b may be a metallic pad (e.g., sputter) on the surface 242 that is not coupled with the circuitry portion 206.

An implementation of ODPs 250-a or 250-b may support a greater quantity of ODPs in a system 200 (e.g., and may support ODPs located within an inner die region). For example, a system 200 (e.g., the system 200-b) that includes ODPs 250-a, ODPs 250-b, or both (e.g., in addition to or as an alternative to ODPs 225) may have a greater quantity of ODPs (e.g., around 110 ODPs or more) than a system (e.g., the system 200-a) that implements ODPs 225 (e.g., without ODPs 250, which may include around 44 ODPs 225).

As an illustrative example of the aspects described herein, a system 200-b may include a substrate 205-b with first circuitry (e.g., substrate circuitry, routing circuitry, power distribution circuitry, or other circuitry, of a circuitry portion 206) and a solder mask material 208 along a surface 215 of the substrate 205-b (e.g., along the x-direction and along the y-direction, with a thickness along the z-direction). In some examples, the substrate 205-b may include a PCB. The system 200-b may also include a semiconductor system 210-b (e.g., one or more dies), which may include second circuitry (e.g., die circuitry, of a circuitry portion 216) of one or more semiconductor dies. The system 200-b may include one or more active pillars 220 (e.g., copper pillars) soldered to the substrate 205-b at a level below (e.g., along the negative z-direction) the solder mask material 208 (e.g., below the surface 242, at the surface 215, with conductors at the surface 215). The one or more active pillars 220 may support a coupling between the die circuitry and the substrate circuitry. The system 200-b may also include one or more ODPs 250 (e.g., ODPs 250-a, ODPs 250-b, or both), which may be soldered to one or more conductors 240 (e.g., copper) of the substrate 205-b at a level above (e.g., along the positive z-direction) the solder mask material 208 (e.g., at the surface 242, with conductors at the surface 242, different than the surface 215, offset from the surface 215 by at least a portion of the solder mask material 208). In some implementations, the substrate 205-b may be or include a second semiconductor system 210 (not shown).

In some examples, the ODP(s) 250 may include a conductive material 222 (e.g., copper) and a conductive material 224 (e.g., solder) that is different than the conductive material 222. In some examples, the conductor(s) 240 may also include the conductive material 222. In some examples, the active pillar(s) 220 support a communicative coupling between the substrate circuitry and the die circuitry, and the ODP(s) 250 may not support a communicative coupling between the substrate circuitry and the die circuitry. In some examples (e.g., for an ODP 250-a), a respective conductor 240 may extend through the solder mask material 208 and may be coupled with a conductor 235 (e.g., a ground plane, formed of copper or some other conductive material) of the substrate 205 below the surface of the solder mask material 208. Additionally, or alternatively, (e.g., for an ODP 250-b) a respective conductor 240 may be above the solder mask material 208 and may be without an electrical connection through the solder mask material 208.

In some examples, a first end (e.g., an end along the negative z-direction, a bottom end) of each of the ODP(s) 250 may be coupled (e.g., soldered) with a respective conductor 240 (e.g., a conductor portion, a landing pad, a pad that supports solder bonding, an interconnection contact point). At a second end opposite the first end (e.g., an end along the positive z-direction, a top end) each of the ODP(s) 250 may be in contact with the polyimide material 212 of the semiconductor system 210-b (e.g., and isolated from the die circuitry).

In some examples, at least a portion of the substrate circuitry (e.g., one or more traces, such as traces along or below a surface 215) may be below the solder mask material 208 and, when viewed along a direction between the substrate 205-b and the semiconductor system 210-b (e.g., along the z-direction), at least partially overlaps at least one of the ODP(s) 250. For example, at least a portion of an ODP 250 may have extents along the x-direction, along the y-direction, or both that overlap with extents along the x-direction, along the y-direction, or both of the substrate circuitry. In some examples, the active pillar(s) 220 may be associated with a first extent (e.g., a first height along the z-direction) from a surface (e.g., a surface 211) of the semiconductor system 210 and the ODP(s) 250 may be associated with a second extent (e.g., a second or height along the z-direction) from the surface of the semiconductor system that is greater than the first extent. In some examples, the semiconductor system 210-b may include one or more dielectric materials 214 (e.g., low-k dielectrics) between the one or more semiconductor dies (e.g., of circuitry portion 216) and a polyimide material 212 between the die circuitry (e.g., and/or between the dielectric materials 214) and the ODP(s) 250. In some examples, the dielectric material(s) 214 may include a silicon oxide, a silicon nitride, some other dielectric material, or any combination thereof.

Thus, by utilizing various techniques herein for enhanced ODP design, systems 200 may support more-robust and reliable mechanisms for bonding semiconductor systems 210 and substrates 205 (e.g., for large DCA implementations, or flip-chip die attachment). For example, by attaching the ODPs 250 to conductors 240 situated at the surface 242 of the solder mask material 208 (e.g., and/or having a connection to a substrate ground plane), systems 200 may support enhanced stability and improved performance. Moreover, such techniques may be implemented at a post silicon design optimization stage for chip-to-package integration, which may reduce design and fabrication complexity. Additionally, in some examples, the ODPs 250-a and 250-b may enable an enhanced ground shielding ring on die corners or surrounding an inner die region.

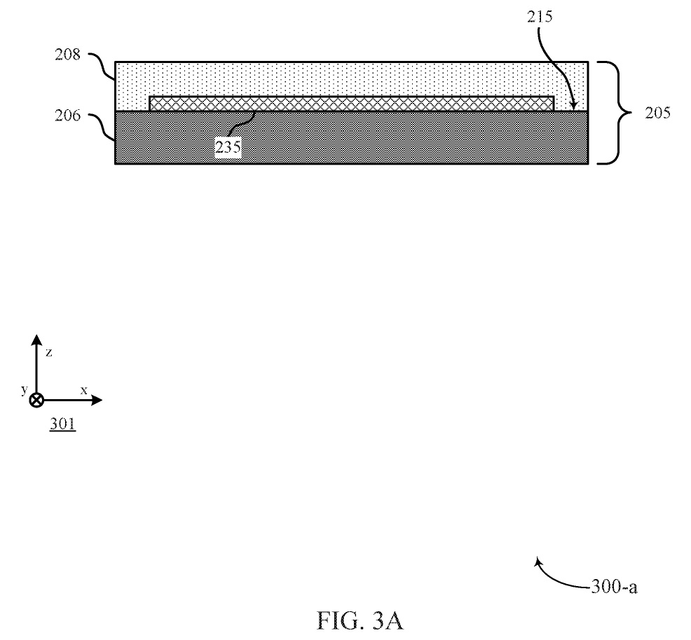

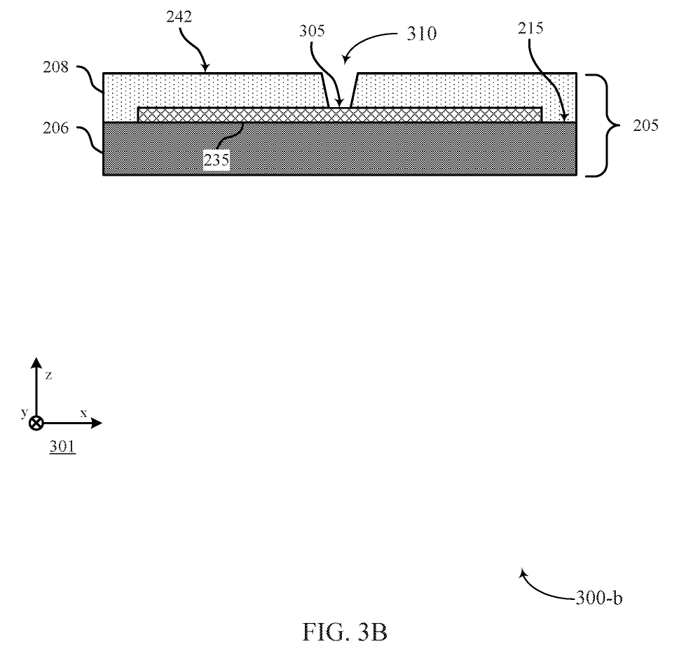

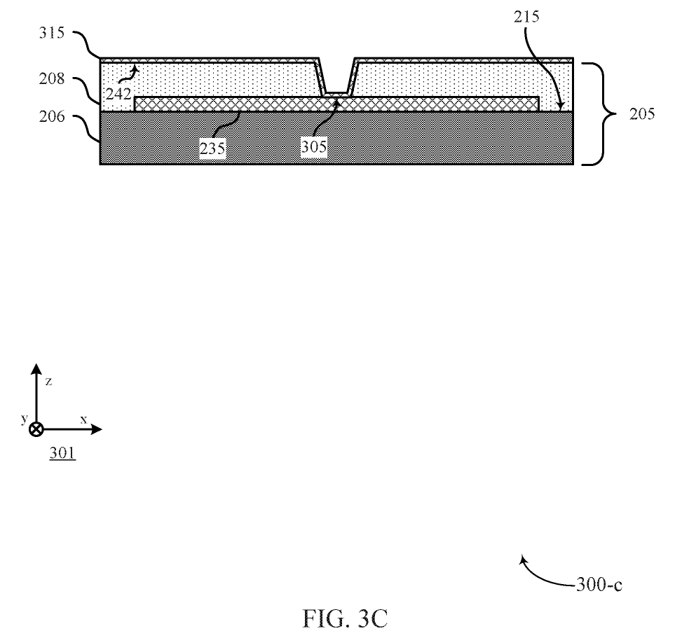

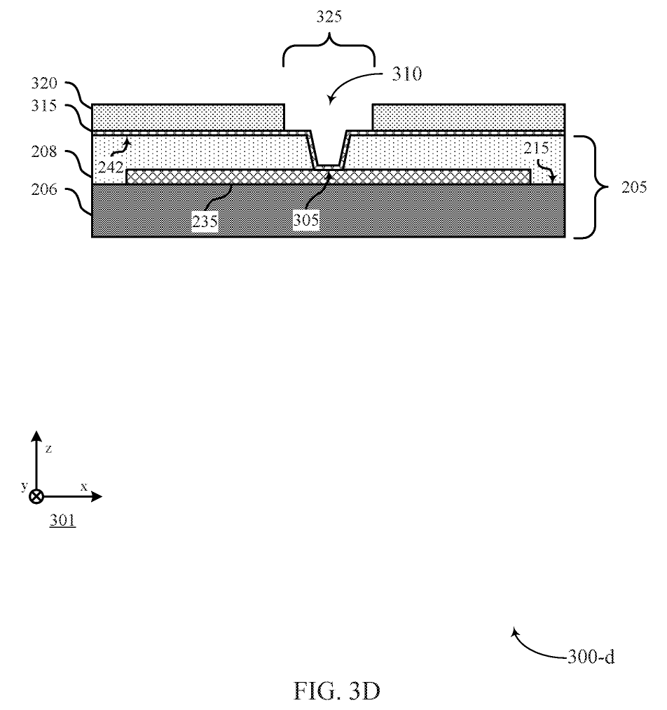

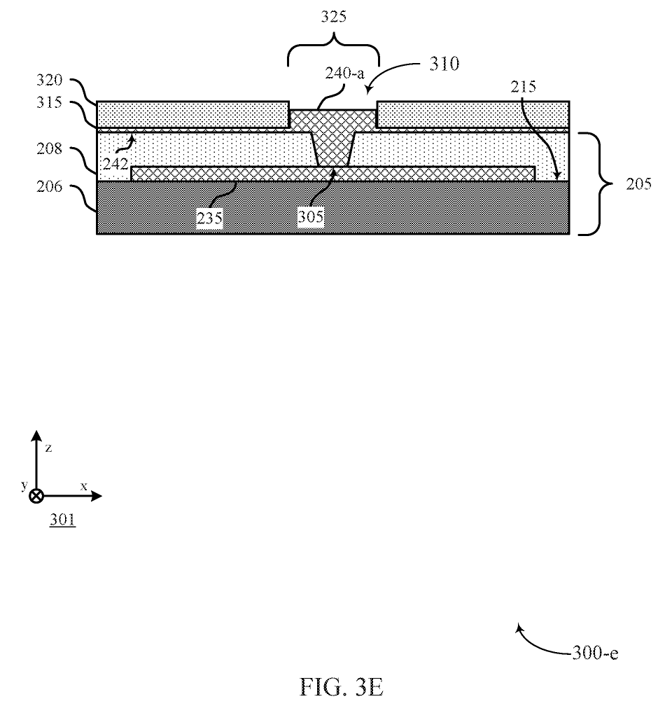

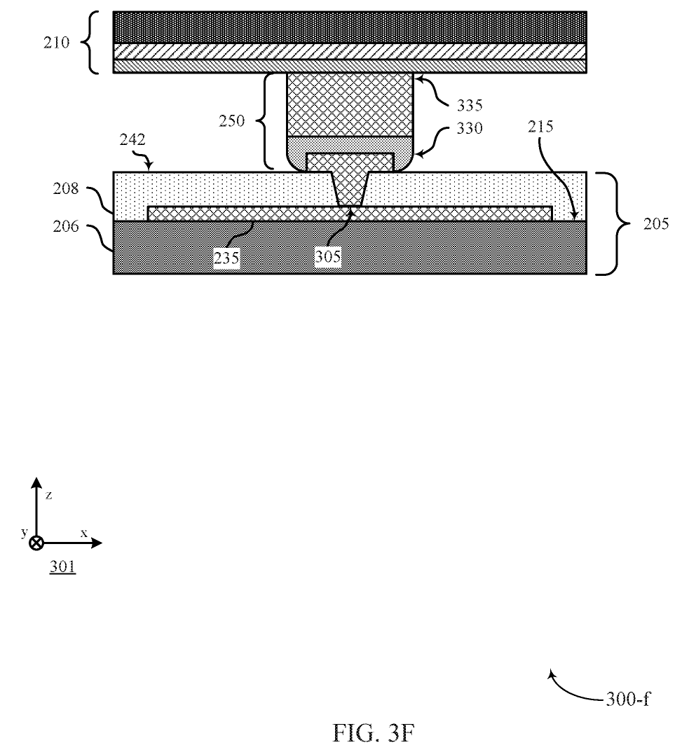

FIGS. 3A through 3F illustrate examples of operations that support interfaces for coupling semiconductor systems with solder-masked substrates in accordance with examples as disclosed herein. Operations are illustrated with reference to a system 300 (e.g., a semiconductor system, a semiconductor stack, a semiconductor device, a semiconductor subcomponent, a stacked DRAM package, a chip-to-package integration), which may be an example of or include a portion of an electronic system (e.g., a system 100, a memory system 110, a host system 105, a system 200-b), or a portion thereof. For example, FIGS. 3A through 3F may illustrate aspects of a first sequence of operations that support manufacturing a system 100 or a portion thereof, a system 200 or a portion thereof, or some other device.

Each of FIGS. 3A through 3F may illustrate aspects of the system 300 after different subsets of the fabrication operations for forming the system 300 (e.g., illustrated as a system 300‑a after a first set of one or more fabrication operations, as a system 300‑b after a second set of one or more fabrication operations, and so on). Each view of FIGS. 3A through 3F may be described with reference to an x-direction, a y-direction, and a z-direction of a coordinate system 301. For example, aspects of the system 300 may be illustrated in accordance with a cut plane (e.g., along an xz-plane) to show embedded features of the system 300. Although, FIGS. 3A through 3F illustrate examples quantities of various features and example dimensionality, the techniques described herein may be applicable for various configurations of such aspects, including greater quantities than shown, fewer quantities than shown, and different dimensionality than shown.

Operations illustrated in and described with reference to FIGS. 3A through 3F may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the system 300. In some examples, operations performed by such a manufacturing system may be supported by a process controller or its components as described herein (e.g., including instructions stored in a non-transitory computer-readable medium that are executable by a processing system to cause the manufacturing system to perform the operations).

In some examples, portions of the system 300 that are illustrated with a same fill pattern may be formed of same or similar materials and portions that are illustrated with different patterns may be formed of different materials. Various material layers are described herein, which may include an aluminum nitride, a silicon carbide, a silicon oxide, a silicon nitride, a silicon carbon nitride, a tetraethyl orthosilicate (TEOS), a boron arsenide, some other dielectric material such as some other oxide or nitride material, or any combination thereof. Additionally, conductive materials described herein may include copper, aluminum, tungsten, titanium, solder, some other conductive material, or any combination thereof.

FIG. 3A shows an example of a cross-sectional view of a system 300-a after a first set of one or more fabrication operations. For example, the first operations may include forming a substrate 205. In some examples, forming the substrate 205 may include forming a circuitry portion 206 and forming (e.g., via a lamination operation) a solder mask material 208 over the circuitry portion 206 (e.g., over at least a portion of the surface 215). In some examples, the substrate 205 may include first circuitry (e.g., routing circuitry, power distribution circuitry, or other substrate circuitry) and one or more conductors 235 (e.g., a ground plane, one or more portions of a ground plane of the substrate 205) at a level (e.g., along the z-direction) below the solder mask material 208.

FIG. 3B shows an example of a cross-sectional view of a system 300-b after a second set of one or more fabrication operations. For example, the second operations may include exposing a surface 305 of the conductor(s) 235 based on forming one or more cavities 310 (e.g., based on laser via formation, a photolithography operation, or some other material removal technique) into a surface 242 of the solder mask material 208.

FIG. 3C shows an example of a cross-sectional view of a system 300-c after a third set of one or more fabrication operations. For example, the third operations may include (e.g., after performing one or more cleaning operations of the top surface) forming a layer of conductive material 315 (e.g., copper) over the surface 242 of the solder mask material 208 and over the exposed surface(s) 305 of the conductor(s) 235. In some examples, forming the layer of the conductive material 315 may include an electroless copper plating operation. In some examples, the electroless copper plating may refer to a process (e.g., a chemical process) used to deposit a layer of copper onto a substrate without the use of an applied electrical voltage or current. Such a process may allow copper to adhere relatively uniformly, for example, based on an ability to achieve uniform thickness over complex geometries, and may provide improved adhesion and a capability to plate non-metallic materials.

FIG. 3D shows an example of a cross-sectional view of a system 300-d after a fourth set of one or more fabrication operations. For example, the fourth operations may include applying a film 320 (e.g., a dry film patterning, a photolithography film) over the layer of the conductive material 315. The film 320 may include one or more openings 325 (e.g., apertures), which may be aligned with the one or more cavities 310.

FIG. 3E shows an example of a cross-sectional view of a system 300-e after a fifth set of one or more fabrication operations. For example, the fifth operations may include forming one or more conductors 240-a in the one or more cavities 310 and above the surface 242 of the solder mask material 208. In some examples, forming the conductor(s) 240-a may include an electrolytic copper plating operation (e.g., performed after the electroless copper plating operation). The electrolytic copper plating operation may refer to a process (e.g., an electrochemical process) used to deposit a layer of copper onto a substrate by passing an electric current through a copper-containing compound (e.g., a copper-containing electrolyte solution, via the layer of conductive material 315). This process may enable a precise control over the thickness and quality of the copper layer, making it suitable for applications associated with high conductivity and may thus provide improved solderability. In some examples, the electrolytic copper plating may be performed through the opening(s) 325 and may be based on forming the layer of the conductive material 315.

FIG. 3F shows an example of a cross-sectional view of a system 300-f after a sixth set of one or more fabrication operations. For example, the sixth operations may include removing the film 320 (e.g., a dry film stripping) and portions of the layer of the conductive material 315 beneath the film after the electrolytic copper plating operation and before bonding the 205 with a semiconductor system 210. In some examples, the sixth operations may include bonding (e.g., soldering) the substrate 205 with a semiconductor system 210. In some examples, the semiconductor system 210 may include second circuitry (e.g., die circuitry, memory array circuitry) of one or more semiconductor dies (e.g., of a circuitry portion 216). In some examples, the bonding operation may include bonding (e.g., soldering) one or more ODPs 250 (e.g., Type 1 ODPs, ODPs 250-a) of the semiconductor system 210 to the one or more conductors 240-a at a level above the solder mask material 208.

Additionally, or alternatively, the bonding may include bonding (e.g., soldering) one or more active pillars 220 (not shown) of the semiconductor system 210 to the substrate 205 at a level below the solder mask material 208. In some examples, the active pillar(s) 220 may couple (e.g., communicatively) circuitry of the semiconductor system 210 with circuitry of the substrate 205. In some examples, an end 330 of each of the ODP(s) 250 may be soldered to a respective one of the one or more conductors 240-a. Additionally, or alternatively, an end 335 of each of the ODP(s) 250 (e.g., located opposite the end 330 along the z-direction), may be in contact with (e.g., bonded with, extend from) a polyimide material of the semiconductor system 210 and may also be isolated from circuitry of the semiconductor system 210.

In some examples, by bonding ODP(s) 250 above the solder mask material 208, a system 300 may support relatively greater quantities of ODPs. As such, electronic packages may be fabricated with increased structural strength and stability, thereby increasing reliability of the system 300 and increasing system lifespan. Additionally, bonding ODP(s) 250 above the solder mask (e.g., at the surface 242) may reduce parasitic capacitance and other interference with the active circuitry (e.g., and other metal layers) of the substrate 205, thereby increasing electrical performance. Moreover, by coupling ODP(s) 250 with a conductor 235 below the surface of the solder mask material 208, the conductive materials of the ODP(s) 250 may be coupled with a common ground plane, which may improve a grounding scheme of the system 300.

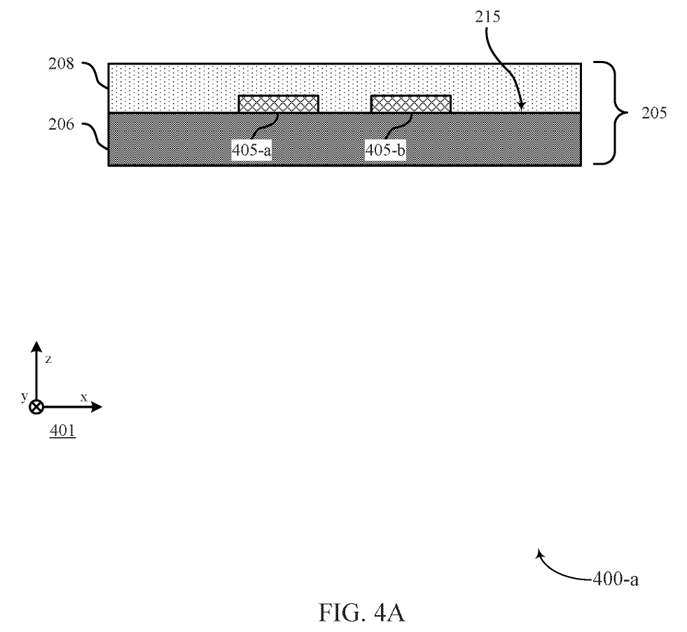

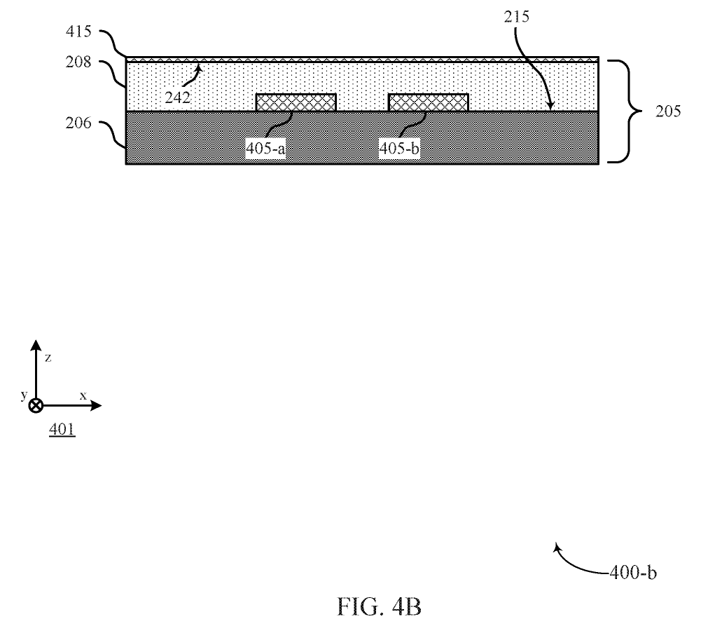

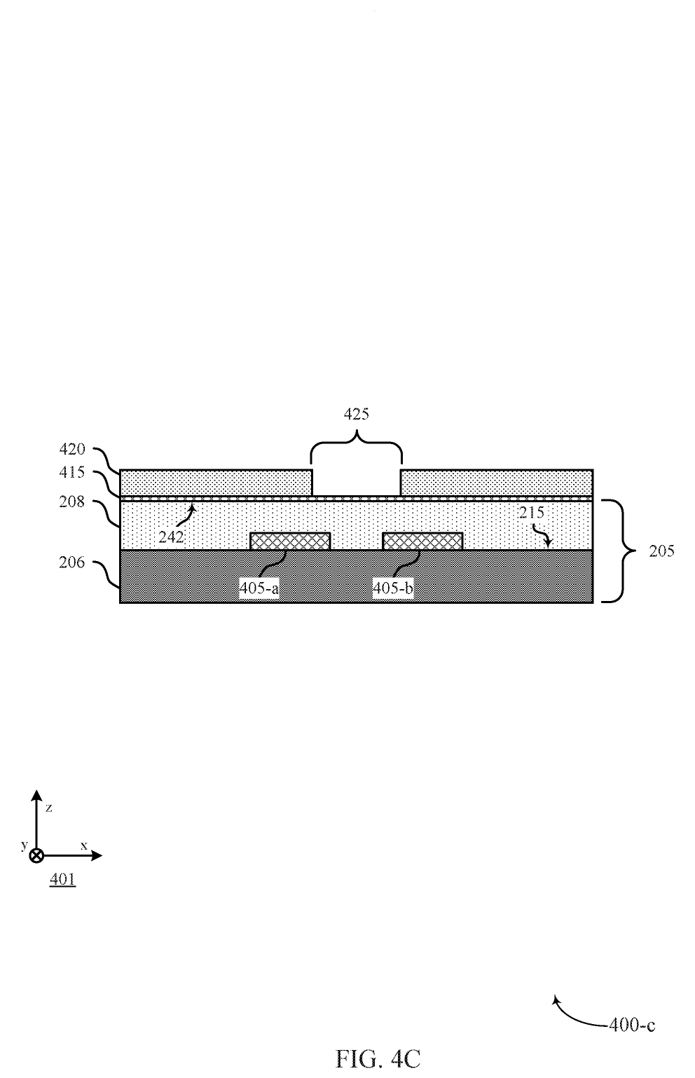

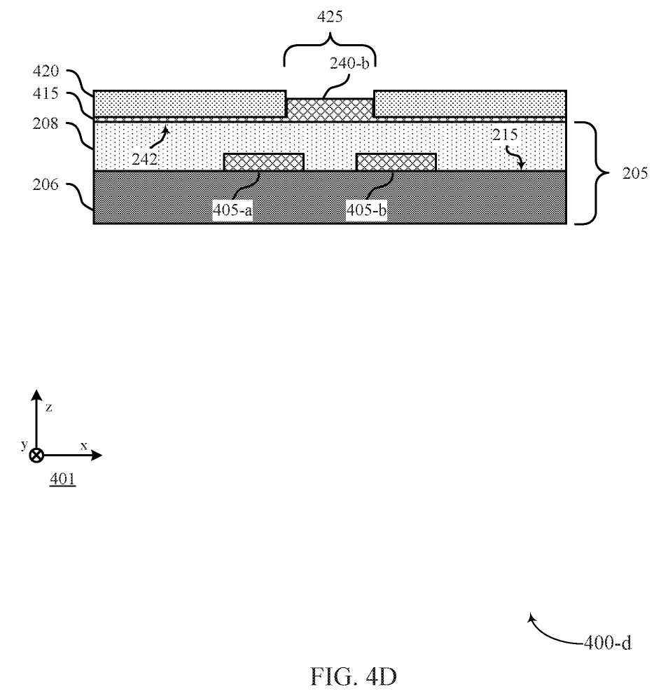

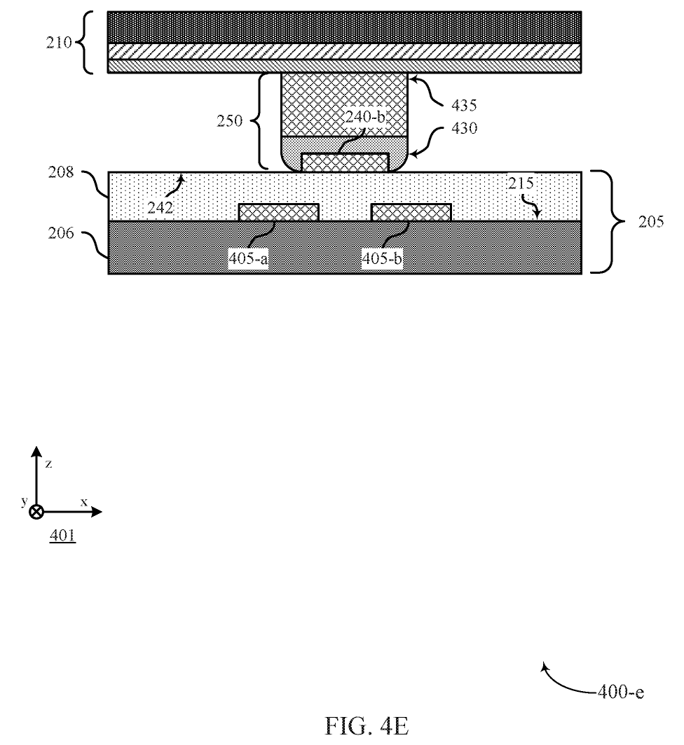

FIGS. 4A through 4E illustrate examples of operations that support interfaces for coupling semiconductor systems with solder-masked substrates in accordance with examples as disclosed herein. Operations are illustrated with reference to a system 400 (e.g., a semiconductor system, a semiconductor stack, a semiconductor device, a semiconductor subcomponent, a stacked DRAM package, a chip-to-package integration), which may be an example of or include an electronic device (e.g., a system 100, a memory system 110, a host system 105, a system 200-b), or a portion thereof. For example, FIGS. 4A through 4E may illustrate aspects of a second sequence of operations that support manufacturing a system 100 or a portion thereof, a system 200 or a portion thereof, or some other device. Operations described with reference to FIGS. 4A through 4E may be performed in addition, or in alterative to the operations described with reference to FIGS. 3A through 3F. For example, one or more or more operations described as being performed with reference to FIGS. 3A through 3F may be performed (e.g., added) in any combination with the operations of FIGS. 4A through 4E, and vice-versa.

Each of FIGS. 4A through 4E may illustrate aspects of the system 400 after different subsets of the fabrication operations for forming the system 400 (e.g., illustrated as a system 400‑a after a first set of one or more fabrication operations, as a system 400‑b after a second set of one or more fabrication operations, and so on). Each view of FIGS. 4A through 4E may be described with reference to an x-direction, a y-direction, and a z-direction of a coordinate system 401. For example, aspects of the system 400 may be illustrated in accordance with a cut plane (e.g., along an xz-plane) to show embedded features of the system 400. Although, FIGS. 4A through 4E illustrate examples quantities of various features and example dimensionality, the techniques described herein may be applicable for various configurations of such aspects, including greater quantities than shown, fewer quantities than shown, and different dimensionality than shown.

Operations illustrated in and described with reference to FIGS. 4A through 4E may be performed by a manufacturing system, such as a semiconductor fabrication system configured to perform additive operations (e.g., deposition, epitaxy, bonding), subtractive operations (e.g., etching, trenching, planarizing, polishing), modifying operations (e.g., oxidizing, doping, reacting, converting), and supporting operations (e.g., masking, patterning, photolithography, aligning), among other operations that support the described techniques for formation of the features of the system 400. In some examples, operations performed by such a manufacturing system may be supported by a process controller or its components as described herein (e.g., including instructions stored in a non-transitory computer-readable medium that are executable by a processing system to cause the manufacturing system to perform the operations).

In some examples, portions of the system 400 that are illustrated with a same fill pattern may be formed of same or similar materials and portions that are illustrated with different patterns may be formed of different materials. Various material layers are described herein, which may include an aluminum nitride, a silicon carbide, a silicon oxide, a silicon nitride, a silicon carbon nitride, a tetraethyl orthosilicate (TEOS), a boron arsenide, some other dielectric material such as some other oxide or nitride material, or any combination thereof. Additionally, conductive materials described herein may include copper, aluminum, tungsten, titanium, some other conductive material, or any combination thereof.

FIG. 4A shows an example of a cross-sectional view of a system 400-a after a first set of one or more fabrication operations. For example, the first operations may include forming a substrate 205. In some examples, forming the substrate 205 may include forming a circuitry portion 206 and forming (e.g., via a lamination operation) a solder mask material 208 over the circuitry portion 206 (e.g., over at least a portion of the surface 215). In some examples, the substrate 205 may include one or more conductors 405 (e.g., a conductor 405-a, a conductor 405-b, conductor portions, ground planes, active circuitry portions) and may include first circuitry (e.g., routing circuitry, power distribution circuitry, or other substrate circuitry, of the circuitry portion 206).

FIG. 4B shows an example of a cross-sectional view of a system 400-b after a second set of one or more fabrication operations. For example, the second operations may include forming a layer of conductive material 415 (e.g., copper) over the surface of the solder mask material 208. In some examples, forming the layer of the conductive material 415 may include an electroless copper plating operation (e.g., in accordance with described techniques for forming the layer of the conductive material 315).

FIG. 4C shows an example of a cross-sectional view of a system 400-c after a third set of one or more fabrication operations. For example, the third operations may include applying a film 420 (e.g., a dry film patterning, a photolithography film) over the layer of the conductive material 415. In some examples, the film 320 may include one or more openings 425 through which an electrolytic copper plating may be performed.

FIG. 4D shows an example of a cross-sectional view of a system 400-d after a fourth set of one or more fabrication operations. For example, the fourth operations may include at least a portion of forming one or more conductors 240-b above the surface 242 and in contact (e.g., direct contact) with the surface 242 of the solder mask material 208 (e.g., via the layer of conductive material 415, based on forming the layer of the conductive material 415). In some examples, forming the conductor 240-b may include an electrolytic copper plating operation after the electroless copper plating operation (e.g., in accordance with the electrolytic copper plating operation for forming the one or more conductors 240-a). In some examples, the conductor(s) 240-b may be formed without a connection to the conductors 405 or other conductor portion (e.g., substrate metal layers, substrate circuitry, ground planes).

FIG. 4E shows an example of a cross-sectional view of a system 400-e after a fifth set of one or more fabrication operations. For example, the fifth operations may include removing the film 420 (e.g., dry film stripping) and portions of the layer of the conductive material 415 beneath the film 420 after the electrolytic copper plating operation and before bonding the substrate 205 with a semiconductor system 210. In some examples, the fifth operations may include bonding (e.g., soldering) the substrate 205 with the semiconductor system 210. In some examples, the semiconductor system 210 may include circuitry (e.g., die circuitry, memory array circuitry) of one or more semiconductor dies (e.g., of a circuitry portion 216). In some examples, the bonding operation may include bonding (e.g., soldering) one or more ODPs 250 (e.g., Type 2 ODPs, ODPs 250-b) of the semiconductor system 210 to the one or more conductors 240-b at a level above the solder mask material 208 (e.g., at the surface 242).

Additionally, or alternatively, the bonding may include bonding (e.g., soldering) one or more active pillars 220 (not shown) of the semiconductor system 210 to the substrate 205 at a level below the solder mask material 208. In some examples, the one or more active pillars 220 may couple (e.g., communicatively) circuitry of the semiconductor system 210 with circuitry of the substrate 205. In some examples, an end 430 of each of the ODP(s) 250 may be soldered to a respective one of the one or more conductors 240-b. Additionally, or alternatively, an end 435 of each of the ODP(s) 250 (e.g., located opposite the end 430 along the z-direction), may be in contact with (e.g., bonded with, extend from) a polyimide material of the semiconductor system 210 and may also be isolated from circuitry of the semiconductor system 210.

In some examples, by bonding ODP(s) 250 above the solder mask material 208, a system 400 may support relatively greater quantities of ODPs. As such, electronic packages may be fabricated with increased structural strength and stability, thereby increasing reliability of the system 400 and increasing system lifespan. Additionally, bonding ODP(s) 250 above the solder mask (e.g., at the surface 242) may reduce parasitic capacitance and other interference with the active circuitry (e.g., and other metal layers) of the substrate 205, thereby increasing electrical performance. Moreover, by coupling ODP(s) 250 with conductor(s) 240-b that are not coupled with circuitry beneath the surface 242, the ODP(s) 250 may be formed at various locations of the system (e.g., along the x-direction, along the y-direction, or both) irrespective of underlying substrate circuitry (e.g., including at portions directly over substrate circuitry).

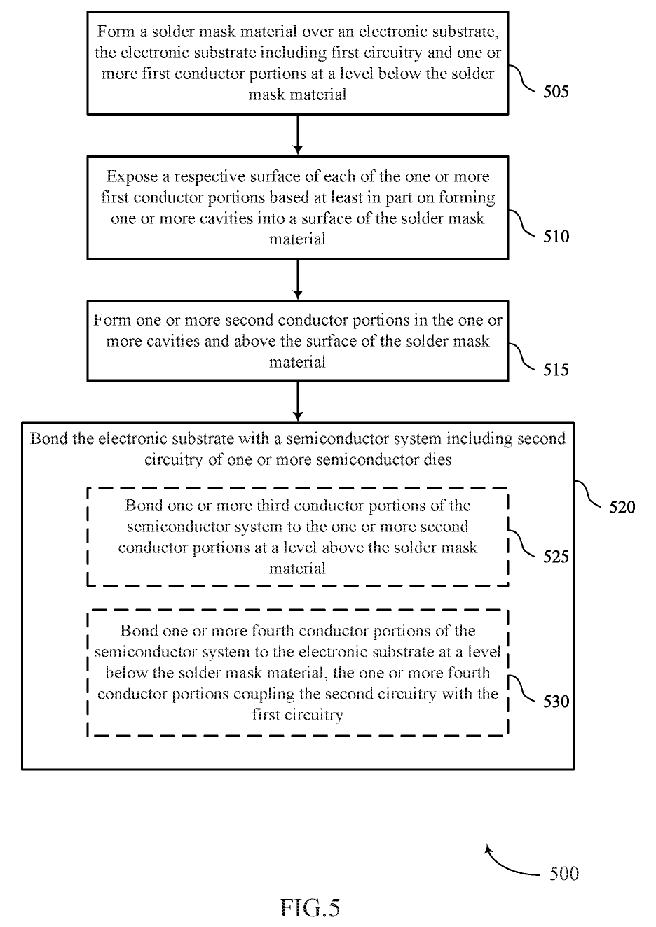

FIG. 5 shows a flowchart illustrating a method or methods 500 that supports interfaces for coupling semiconductor systems with solder-masked substrates in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a solder mask material over an electronic substrate, the electronic substrate including first circuitry and one or more first conductor portions at a level below the solder mask material.

At 510, the method may include exposing a respective surface of each of the one or more first conductor portions based at least in part on forming one or more cavities into a surface of the solder mask material.

At 515, the method may include forming one or more second conductor portions in the one or more cavities and above the surface of the solder mask material.

At 520, the method may include bonding the electronic substrate with a semiconductor system including second circuitry of one or more semiconductor dies. For example, at 525, the method may include bonding one or more third conductor portions of the semiconductor system to the one or more second conductor portions at a level above the solder mask material. In some examples, at 530, the method may also include bonding one or more fourth conductor portions of the semiconductor system to the electronic substrate at a level below the solder mask material, the one or more fourth conductor portions coupling the second circuitry with the first circuitry.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a solder mask material over an electronic substrate, the electronic substrate including first circuitry and one or more first conductor portions at a level below the solder mask material; exposing a respective surface of each of the one or more first conductor portions based at least in part on forming one or more cavities into a surface of the solder mask material; forming one or more second conductor portions in the one or more cavities and above the surface of the solder mask material; and bonding the electronic substrate with a semiconductor system including second circuitry of one or more semiconductor dies, where the bonding includes: bonding one or more third conductor portions of the semiconductor system to the one or more second conductor portions at a level above the solder mask material.

Aspect 2: The method or apparatus of aspect 1, where a first end of each of the one or more third conductor portions is soldered to a respective one of the one or more second conductor portions and a second end of each of the one or more third conductor portions, opposite the first end, is in contact with a polyimide material of the semiconductor system and isolated from the second circuitry.

Aspect 3: The method or apparatus of any of aspects 1 through 2, where the one or more first conductor portions are associated with (e.g., coupled with, a portion of) a ground plane of the electronic substrate.

Aspect 4: The method or apparatus of any of aspects 1 through 3, further including operations, features, circuitry, logic, means, or instructions, or any combination thereof for forming a layer of conductive material over the surface of the solder mask material and over the respective exposed surface of the one or more first conductor portions, where forming the one or more second conductor portions is based at least in part on forming the layer of the conductive material.

Aspect 5: The method or apparatus of aspect 4, where forming the layer of the conductive material includes an electroless copper plating operation and forming the one or more second conductor portions includes an electrolytic copper plating operation after the electroless copper plating operation.

Aspect 6: The method or apparatus of aspect 5, further including operations, features, circuitry, logic, means, or instructions, or any combination thereof for applying a film over the layer of the conductive material, the film including one or more openings aligned with the one or more cavities, where the electrolytic copper plating operation is performed through the one or more openings.

Aspect 7: The method or apparatus of aspect 6, further including operations, features, circuitry, logic, means, or instructions, or any combination thereof for removing the film and portions of the layer of the conductive material beneath the film after the electrolytic copper plating operation and before bonding the electronic substrate with the semiconductor system.

Aspect 8: The method or apparatus of any of aspects 1 through 7, where bonding the electronic substrate with the semiconductor system includes bonding one or more fourth conductor portions of the semiconductor system to the electronic substrate at a level below the solder mask material, the one or more fourth conductor portions coupling the second circuitry with the first circuitry.

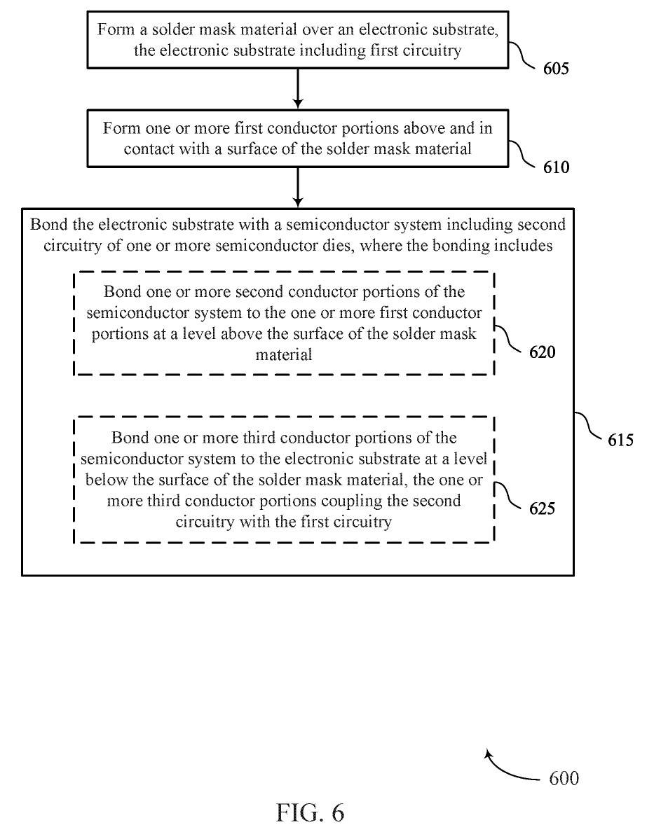

FIG. 6 shows a flowchart illustrating a method or methods 600 that supports interfaces for coupling semiconductor systems with solder-masked substrates in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include forming a solder mask material over an electronic substrate, the electronic substrate including first circuitry.

At 610, the method may include forming one or more first conductor portions above and in contact with a surface of the solder mask material.

At 615, the method may include bonding the electronic substrate with a semiconductor system including second circuitry of one or more semiconductor dies. For example, at 620, the method may include bonding one or more second conductor portions of the semiconductor system to the one or more first conductor portions at a level above the surface of the solder mask material. In some examples, at 625, the method may also include bonding one or more third conductor portions of the semiconductor system to the electronic substrate at a level below the surface of the solder mask material, the one or more third conductor portions coupling the second circuitry with the first circuitry.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 9: A method or apparatus including operations, features, circuitry, logic, means, or instructions, or any combination thereof for forming a solder mask material over an electronic substrate, the electronic substrate including first circuitry; forming one or more first conductor portions above and in contact with a surface of the solder mask material; bonding the electronic substrate with a semiconductor system including second circuitry of one or more semiconductor dies, where the bonding includes: bonding one or more second conductor portions of the semiconductor system to the one or more first conductor portions at a level above the surface of the solder mask material.

Aspect 10: The method or apparatus of aspect 9, where a first end of each of the one or more second conductor portions is soldered to a respective one of the one or more first conductor portions and a second end of each of the one or more second conductor portions, opposite the first end, is in contact with a polyimide material of the semiconductor system and isolated from the second circuitry.

Aspect 11: The method or apparatus of any of aspects 9 through 10, further including operations, features, circuitry, logic, means, or instructions, or any combination thereof for forming a layer of conductive material over the surface of the solder mask material, where forming the one or more first conductor portions is based at least in part on forming the layer of the conductive material.

Aspect 12: The method or apparatus of aspect 11, where forming the layer of the conductive material includes an electroless copper plating operation and forming the one or more first conductor portions includes an electrolytic copper plating operation after the electroless copper plating operation.

Aspect 13: The method or apparatus of aspect 12, further including operations, features, circuitry, logic, means, or instructions, or any combination thereof for applying a film over the layer of the conductive material, the film including one or more openings, where the electrolytic copper plating operation is performed through the one or more openings.

Aspect 14: The method or apparatus of aspect 13, further including operations, features, circuitry, logic, means, or instructions, or any combination thereof for removing the film and portions of the layer of the conductive material beneath the film after the electrolytic copper plating operation and before bonding the electronic substrate with the semiconductor system.

Aspect 15: The method or apparatus of any of aspects 9 through 14, where bonding the electronic substrate with the semiconductor system includes: bonding one or more third conductor portions of the semiconductor system to the electronic substrate at a level below the surface of the solder mask material, the one or more third conductor portions coupling the second circuitry with the first circuitry.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 16: An electronic system, including: an electronic substrate including first circuitry and a solder mask material along a surface of the electronic substrate; and a semiconductor system including second circuitry of one or more semiconductor dies and one or more first conductor portions soldered to one or more second conductor portions of the electronic substrate at a level above the solder mask material.

Aspect 17: The electronic system of aspect 16, further including one or more third conductor portions of the semiconductor system soldered to the electronic substrate at a level below the solder mask material and coupling the second circuitry with the first circuitry.

Aspect 18: The electronic system of aspect 17, where: the one or more third conductor portions are associated with a first extent from a surface of the semiconductor system; and the one or more first conductor portions are associated with a second extent from the surface of the semiconductor system that is greater than the first extent.

Aspect 19: The electronic system of any of aspects 17 through 18, where the one or more third conductor portions support a communicative coupling between the first circuitry and the second circuitry and the one or more first conductor portions do not support a communicative coupling between the first circuitry and the second circuitry.

Aspect 20: The electronic system of any of aspects 16 through 19, where: the one or more second conductor portions extend through the solder mask material and are coupled with a ground plane of the electronic substrate below the surface of the solder mask material.

Aspect 21: The electronic system of any of aspects 16 through 20, where the one or more second conductor portions are above the solder mask material and without an electrical connection through the solder mask material.

Aspect 22: The electronic system of any of aspects 16 through 21, where: a first end of each of the one or more first conductor portions is soldered to a respective one of the one or more second conductor portions, and a second end of each of the one or more first conductor portions, opposite the first end, is in contact with a polyimide material of the semiconductor system and isolated from the second circuitry.

Aspect 23: The electronic system of any of aspects 16 through 22, where: a portion of the first circuitry is below the solder mask material and, when viewed along a direction between the electronic substrate and the semiconductor system, at least partially overlaps at least one of the one or more first conductor portions.

Aspect 24: The electronic system of any of aspects 16 through 23, where the semiconductor system includes one or more dielectric materials between the one or more semiconductor dies and a polyimide material between the second circuitry and the one or more first conductor portions.

Aspect 25: The electronic system of aspect 24, where the one or more dielectric materials include a silicon oxide, a silicon nitride, or both.

Aspect 26: The electronic system of any of aspects 16 through 25, where: the one or more first conductor portions include a first conductive material and a second conductive material different than the first conductive material, and the one or more second conductor portions include the first conductive material.

Aspect 27: The electronic system of any of aspects 16 through 26, where the electronic substrate includes a printed circuit board (PCB) or a second semiconductor system.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An electronic system, comprising:
an electronic substrate comprising first circuitry and a solder mask material along a surface of the electronic substrate; and
a semiconductor system comprising second circuitry of one or more semiconductor dies and one or more first conductor portions soldered to one or more second conductor portions of the electronic substrate at a level above the solder mask material.

2. The electronic system of claim 1, further comprising:
one or more third conductor portions of the semiconductor system soldered to the electronic substrate at a level below the solder mask material and coupling the second circuitry with the first circuitry.

3. The electronic system of claim 2, wherein:
the one or more third conductor portions are associated with a first extent from a surface of the semiconductor system; and
the one or more first conductor portions are associated with a second extent from the surface of the semiconductor system that is greater than the first extent.

4. The electronic system of claim 2, wherein the one or more third conductor portions support a communicative coupling between the first circuitry and the second circuitry and the one or more first conductor portions do not support a communicative coupling between the first circuitry and the second circuitry.

5. The electronic system of claim 1, wherein:
the one or more second conductor portions extend through the solder mask material and are coupled with a ground plane of the electronic substrate below the surface of the solder mask material.

6. The electronic system of claim 1, wherein the one or more second conductor portions are above the solder mask material and without an electrical connection through the solder mask material.

7. The electronic system of claim 1, wherein:
a first end of each of the one or more first conductor portions is soldered to a respective one of the one or more second conductor portions, and
a second end of each of the one or more first conductor portions, opposite the first end, is in contact with a polyimide material of the semiconductor system and isolated from the second circuitry.

8. The electronic system of claim 1, wherein:
a portion of the first circuitry is below the solder mask material and, when viewed along a direction between the electronic substrate and the semiconductor system, at least partially overlaps at least one of the one or more first conductor portions.

9. The electronic system of claim 1, wherein the semiconductor system comprises one or more dielectric materials between the one or more semiconductor dies and a polyimide material between the second circuitry and the one or more first conductor portions.

10. The electronic system of claim 9, wherein the one or more dielectric materials comprise a silicon oxide, a silicon nitride, or both.

11. The electronic system of claim 1, wherein:
the one or more first conductor portions comprise a first conductive material and a second conductive material different than the first conductive material, and
the one or more second conductor portions comprise the first conductive material.

12. The electronic system of claim 1, wherein the electronic substrate comprises a printed circuit board (PCB) or a second semiconductor system.

13. A method of electronic system formation, comprising:
forming a solder mask material over an electronic substrate, the electronic substrate comprising first circuitry and one or more first conductor portions at a level below the solder mask material;
exposing a respective surface of each of the one or more first conductor portions based at least in part on forming one or more cavities into a surface of the solder mask material;
forming one or more second conductor portions in the one or more cavities and above the surface of the solder mask material; and
bonding the electronic substrate with a semiconductor system comprising second circuitry of one or more semiconductor dies, wherein the bonding comprises:
bonding one or more third conductor portions of the semiconductor system to the one or more second conductor portions at a level above the solder mask material.

14. The method of claim 13, wherein bonding the electronic substrate with the semiconductor system further comprises:
bonding one or more fourth conductor portions of the semiconductor system to the electronic substrate at a level below the solder mask material, the one or more fourth conductor portions coupling the second circuitry with the first circuitry.

15. The method of claim 13, wherein:
a first end of each of the one or more third conductor portions is soldered to a respective one of the one or more second conductor portions, and
a second end of each of the one or more third conductor portions, opposite the first end, is in contact with a polyimide material of the semiconductor system and isolated from the second circuitry.

16. The method of claim 13, wherein the one or more first conductor portions are associated with a ground plane of the electronic substrate.

17. The method of claim 13, further comprising:
forming a layer of conductive material over the surface of the solder mask material and over the respective exposed surface of the one or more first conductor portions, wherein forming the one or more second conductor portions is based at least in part on forming the layer of the conductive material.

18. The method of claim 17, wherein:
forming the layer of the conductive material comprises an electroless copper plating operation, and
forming the one or more second conductor portions comprises an electrolytic copper plating operation after the electroless copper plating operation.

19. The method of claim 18, further comprising:
applying a film over the layer of the conductive material, the film comprising one or more openings aligned with the one or more cavities, wherein the electrolytic copper plating operation is performed through the one or more openings; and
removing the film and portions of the layer of the conductive material beneath the film after the electrolytic copper plating operation and before bonding the electronic substrate with the semiconductor system.

20. A method of semiconductor system formation, comprising:
forming a solder mask material over an electronic substrate, the electronic substrate comprising first circuitry;
forming one or more first conductor portions above and in contact with a surface of the solder mask material; and
bonding the electronic substrate with a semiconductor system comprising second circuitry of one or more semiconductor dies, wherein the bonding comprises:
bonding one or more second conductor portions of the semiconductor system to the one or more first conductor portions at a level above the surface of the solder mask material.

21. The method of claim 20, wherein bonding the electronic substrate with the semiconductor system further comprises:
bonding one or more third conductor portions of the semiconductor system to the electronic substrate at a level below the surface of the solder mask material, the one or more third conductor portions coupling the second circuitry with the first circuitry.

22. The method of claim 20, wherein:
a first end of each of the one or more second conductor portions is soldered to a respective one of the one or more first conductor portions, and
a second end of each of the one or more second conductor portions, opposite the first end, is in contact with a polyimide material of the semiconductor system and isolated from the second circuitry.

23. The method of claim 20, further comprising:
forming a layer of conductive material over the surface of the solder mask material, wherein forming the one or more first conductor portions is based at least in part on forming the layer of the conductive material.

24. The method of claim 23, wherein:
forming the layer of the conductive material comprises an electroless copper plating operation, and
forming the one or more first conductor portions comprises an electrolytic copper plating operation after the electroless copper plating operation.

25. The method of claim 24, further comprising:
applying a film over the layer of the conductive material, the film comprising one or more openings, wherein the electrolytic copper plating operation is performed through the one or more openings; and
removing the film and portions of the layer of the conductive material beneath the film after the electrolytic copper plating operation and before bonding the electronic substrate with the semiconductor system.
